(19) United States
(12) Patent Application Publication
(10) Pub. No.: US 2021/0189586 A1
(43) Pub. Date: Jun. 24, 2021

(54) SELECTIVE EPITAXIAL ATOMIC REPLACEMENT: PLASMA ASSISTED ATOMIC LAYER FUNCTIONALIZATION OF MATERIALS

(71) Applicants: Sefaattin Tongay, Tempe, AZ (US); Dipesh Trivedi, Tempe, AZ (US); Guven Turgut, Tempe, AZ (US); Mohammed Sayyad, Tempe, AZ (US); Ying Qin, Tempe, AZ (US)

(72) Inventors: Sefaattin Tongay, Tempe, AZ (US); Dipesh Trivedi, Tempe, AZ (US); Guven Turgut, Tempe, AZ (US); Mohammed Sayyad, Tempe, AZ (US); Ying Qin, Tempe, AZ (US)

(21) Appl. No.: 17/127,364

(22) Filed: Dec. 18, 2020

Related U.S. Application Data
(60) Provisional application No. 62/949,605, filed on Dec. 18, 2019.

(51) Int. Cl. C30B 1/02; C01B 19/04; C03C 17/23; C04B 35/468

(52) U.S. Cl. CPC C30B 1/023; C04B 35/4682; C03C 17/23; C01B 19/04

(57) ABSTRACT

Forming a two-dimensional Janus layer includes forming a layer of MX₂, where M is a transition metal and X is a first chalcogen, plasma etching the layer of MX₂ to remove X from the top layer, thereby yielding an etched layer, and contacting the etched layer with a second chalcogen Y. The second chalcogen is different than the first chalcogen, resulting in a two-dimensional Janus layer including MXY.

### CROSS-REFERENCE TO RELATED APPLICATION

This application claims the benefit of U.S. Patent Application No. 62/949,605 entitled “PLASMA ASSISTED ATOMIC LAYER FUNCTIONALIZATION OF MATERIALS” and filed on Dec. 18, 2019, which is incorporated by reference herein in its entirety.

### TECHNICAL FIELD

This invention relates to synthesis of highly crystalline epitaxial grade Janus transition metal dichalcogenides (TMDC) materials.

### BACKGROUND

2D Transition metal dichalcogenides (TMDs) are a class of 2D material systems with the general chemical formula MX₂ where M is transition metal atom Mo, Nb, Ti, etc. and X is the chalcogen atom S, Se, or Te. When M atoms are selected from group-VIB elements Mo or W, they form MoS₂, WSe₂, or MoTe₂ and these materials behave as direct gap semiconductors in the monolayer limit. Since the inversion symmetry is broken and the spin orbit coupling (SOC) is large, 2D group-VI TMDs have exotic band structures with individually controllable valleys in K-space at the K and K′ points in the first Brillouin zone. The combination of the spin and valley degrees of freedom means that optically generated electrons and holes are both valley and spin polarized (spin-valley locking). This quantum property is absent in other traditional semiconductors.

While classical TMD surfaces have the same type of chacogen atoms, 2D Janus TMDs have different chalcogens on each side. Named after the two-faced Roman God, ‘Janus’, each face (surface) of Janus sheet contains different types of atoms. Janus layers have been experimentally stabilized using chemical vapor deposition (CVD). However, this stabilization involves high processing temperatures which typically result in defects. The irreproducibility and lack of epitaxial quality has made it difficult to probe quantum effects in Janus layers.

### SUMMARY

In a first general aspect, forming a two-dimensional Janus layer includes forming a layer including MX₂, where M is a transition metal and X is a first chalcogen, plasma etching the layer including MX₂ to remove X from the top layer, thereby yielding an etched layer, and contacting the etched layer with a second chalcogen Y. The second chalcogen is different than the first chalcogen, resulting in a two-dimensional Janus layer including MXY.

Implementations of the general aspect may include one or more of the following features.

In some implementations, forming the layer including MX₂ includes reacting a transition metal-containing compound with a chalcogen in a tube furnace to yield a transition metal-containing chalcogenide compound.

In some implementations, reacting the transition metal-containing chalcogenide compound with the hydrogen radicals removes a layer of a chalcogen surface to yield a reduced transition-metal containing compound.

Some implementations include reacting the reduced transition metal-containing compound with the first chalcogen to yield the layer including MX₂.

In some implementations, removing X and adding Y occur simultaneously.

In some implementations, the transition metal is selected from the group consisting of Mo, Nb, Ti, V, Cr, Mn, and W. The first chalcogen and the second chalcogen are typically selected from the group consisting of O, S, Se, and Te.

In some implementations, plasma etching the layer including MX₂ occurs at a pressure less than atmospheric pressure. The plasma etching can include etching with a hydrogen plasma containing hydrogen radicals. Some implementations further include reacting hydrogen free radicals from the hydrogen plasma with the second chalcogen to yield H₂Y. The H₂Y can dissociate to yield Y radicals.

In some implementations, contacting the etched layer with the second chalcogen includes reacting the Y radicals with the etched layer.

In some implementations, the layer including MX₂ is positioned proximate a tail of the plasma.

Some implementations further include thermal sulfurization of the layer including MXY.

In some implementations, the two-dimensional Janus layer is a monolayer.

In some implementations, the two-dimensional Janus layer is formed without alloying.

In some implementations, the first general aspect occurs at room temperature and yields lateral and vertical heterojunctions of Janus layers.

A second general aspect includes a two-dimensional Janus layer formed by the first general aspect.

Implementations of the second general aspect may include one or more of the following features.

In some implementations, the two-dimensional Janus layer lacks inversion symmetry and mirror symmetry.

In some implementations, the two-dimensional Janus layer has a thickness of about 1 nm.

Innovative aspects described herein allow for optical, electrical, and quantum grade materials to be manufactured by methods including epitaxial chalcogen replacement to stabilize Janus 2D layers. The described methodology is not specific to one particular system, but is applicable to other systems, such as MoS Se, WSSe, MoSTe, and others. The process can be extended to other chalcogen containing two-dimensional materials. Plasma assisted atomic layer functionalization of materials (PA-ALFM) is carried out at room temperature, thus enabling an energy conservative approach with fine control over the crystal structure that would otherwise be hindered by a higher thermal gradient. PA-ALFM can be adapted to current industrial standards and material systems. Room temperature synthesis enables good quality control, and as a result optical grade material can be synthesized. Room temperature processing also allows for creating complex vertical and heterostructures of these materials (vertical heterojunction Janus and lateral heterojunction Janus). Fast, in situ processing limits foreign contamination. Other advantages include high precision and selective layer replacement, short operation times, effective and efficient use of material, minimal contamination probability, and adaptability to current industrial standards.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF DRAWINGS

FIGS. 1A-1C depict synthesis of a two-dimensional (2D) Janus layer.

FIGS. 2A and 2B show photoluminescence spectra and Raman spectra, respectively, of classical and Janus 2D transition metal dichalcogenides (TMDs) for different chemical compositions.

FIG. 3 is a schematic diagram depicting synthesis of 2D Janus layers with plasma assisted-atomic layer functionalization of materials (PA-ALFM).

FIG. 4 depicts proposed mechanism details for the synthesis of two-dimensional (2D) Janus layers with PA-ALFM.

FIGS. 5A and 5B show a Raman spectrum and phonon dispersion, respectively, of 2D Janus layers of WSSe.

FIGS. 6A and 6B show Raman spectra of WSe₂ and 2D Janus layers of MoSSe and phonon dispersion of MoSSe, respectively.

FIG. 7A shows Raman spectra of MoS₂ (top), 2D Janus layers of MoSSe (middle), and MoSe2 (bottom). FIG. 7B shows photoluminescence (PL) spectra of MoS₂ (right), 2D Janus layers of MoSSe (middle), and MoSe₂ (left).

FIG. 8A shows Raman spectra of WS₂ (top), 2D Janus layers of WSSe (middle), and WSe₂ (bottom). FIG. 8B shows PL spectra of WS₂ (right), 2D Janus layers of WSSe (middle), and WSe₂ (left).

FIG. 9A shows Raman mapping of Janus MoSSe at 290 cm⁻¹. FIG. 9B shows Raman mapping of Janus WSSe at 284 cm⁻¹.

FIGS. 10A and 10B show atomic force microscope (AFM) images of MoSe₂ and MoSSe, respectively. The insets show Raman mapping of peaks at 250 cm⁻¹ (WSe₂A₁′ mode) and 284 cm⁻¹ (WSSeA₁ mode), respectively.

FIGS. 11A and 11B show HAADF STEM images of MoSSe and WSSe, respectively, showing hexagonal lattice structure and spacing of (100) and (110) planes. The inset shows line profile along the dashed line and FFT image.

FIGS. 12A and 12B show PL spectra and integrated PL intensity, respectively, of MoSSe.

FIGS. 13A and 13B show PL spectra and integrated PL intensity, respectively, of WSSe.

FIG. 14A shows excitonic and optical quality of synthesized Janus SeMoS monolayer evidenced by low temperature photoluminescence spectroscopy. FIG. 14B shows overall PL intensity mapping on triangular flake, and FIG. 14C shows peak area versus temperature.

FIG. 15A shows excitonic and optical quality of synthesized Janus SeWS monolayer evidenced by low temperature photoluminescence spectroscopy. FIG. 15B shows overall PL intensity mapping on triangular flake, and FIG. 15C shows peak area versus temperature.

FIG. 16 shows Varshni law

$${E}_{g} ( T ) = {E}_{g} ( 0 ) - \frac{α {T}^{2}}{T + β} ,$$

and fitting of PL peak shift trend of Janus SeWS and SeMoS.

FIG. 17A is an image of Janus MoSSe showing a plasma effect with severe cracking and over etching due to intense plasma bombardment. FIG. 17B shows MoSSe Raman spectra under intense bombardment.

FIG. 18 shows a Raman spectrum of randomized alloying effect while performing high temperature thermal sulfurization showing the non-repeatability of previous claims of Janus structure formation.

FIG. 19 depicts a lateral Janus heterostructure.

FIGS. 20A and 20B depict vertical Janus heterostructures.

### DETAILED DESCRIPTION

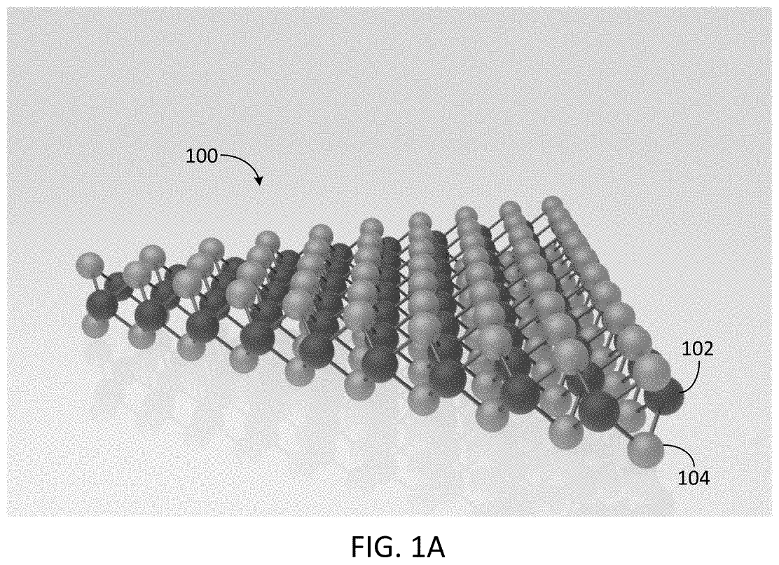

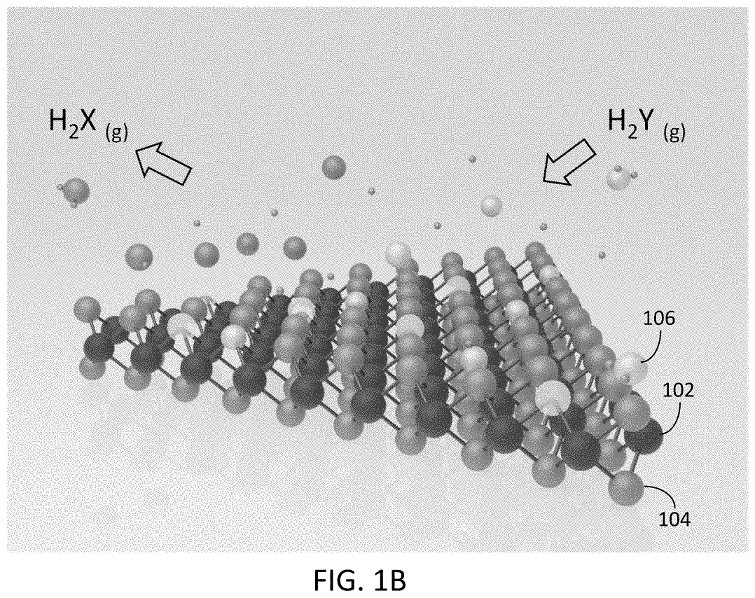

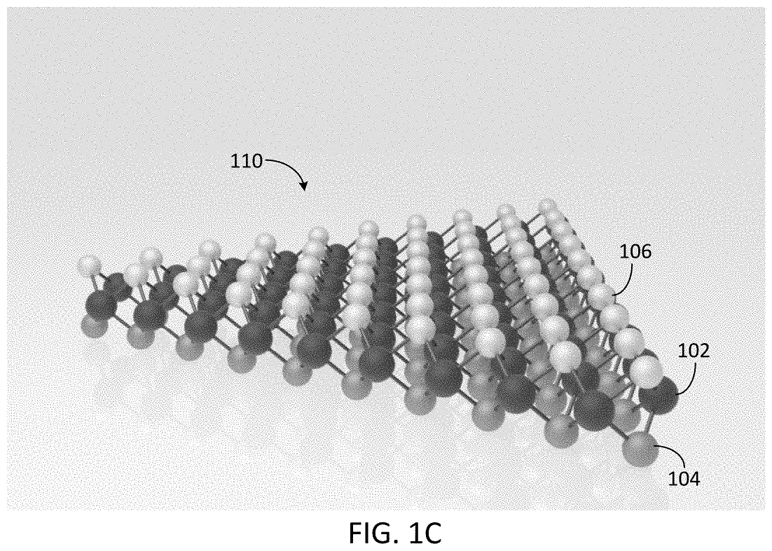

FIGS. 1A-1C depict synthesis of a two-dimensional (2D) Janus layer. This “epitaxial chalcogen replacement” process starts with CVD growth of classical transition metal dichalcogenides (TMDs) 100 as depicted in FIG. 1A with the chemical formula of MX₂ (M=Mo, W and X═S, Se, or Te), where M and X are represented by reference numerals 102 and 104, respectively. Without breaking the vacuum, a gentle H₂ plasma is created using a 15W RF power source and matching LRC network to remove each X atom from the surface. During this process, as depicted in FIG. 1B, following the principles of reactive ion etching, hydrogen free radicals are adsorbed on the top chalcogen atomic sites of CVD grown samples, resulting in weakening of the MX bond for the surface atoms. At the same time, these bonds are bombarded by hydrogen ions present in hydrogen plasma, resulting into formation of chalcogen vacancies (VX) on top of the metal site as the top chalcogen atoms leaves the site in the form of H₂X (g). These Vₓ vacancy sites are rapidly filled by free Y chalcogen radicals 106 created by disassociation of the supplied H₂Y gas molecules following the principles of plasma enhanced CVD technique. FIG. 1C depicts a MXY 2D Janus layer 110 where M is a transition metal atom 102 (e.g., Mo, Nb, Ti, V, Cr, Mn, W, etc.) and X and Y are different chalcogen atom 104 and 106, respectively, with X 104 on a first surface, Y 106 on a second surface, and M 102 between X and Y.

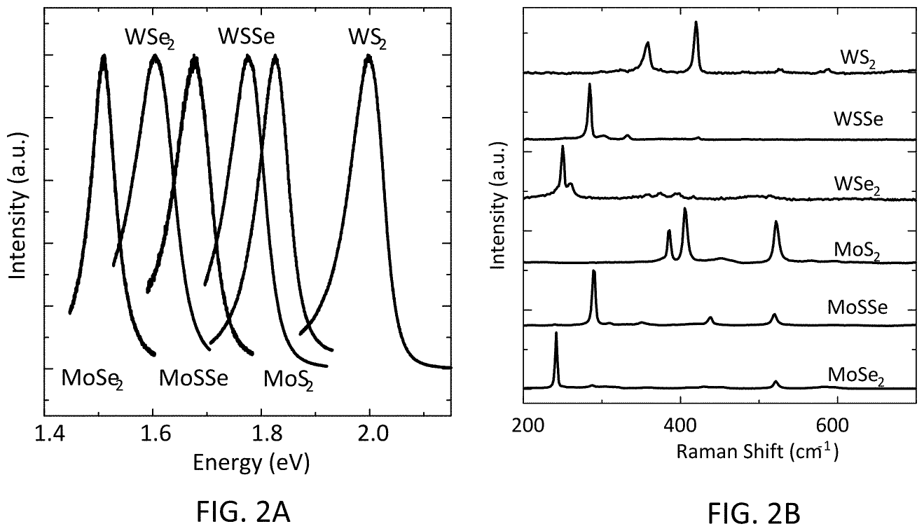

This process can be used to synthesize optical/excitonic grade 2D Janus crystals. As shown in FIGS. 2A and 2B, respectively, 2D Janus layers exhibit very strong photoluminescence with quantum efficiencies as high as 20% and sharp Raman signals (FWHM˜3-4 cm⁻'). RF plasma power, H₂Y gas pressure, and process duration time can be varied to achieve highly crystalline 2D Janus layers. Raman spectroscopy, PL, XPS, EDS, and TEM can be used to make correlations between the process parameters, crystallinity, and overall excitonic performance, thereby allowing reduction of point defects, spectral broadening, and eliminate bound exciton complexes.

Synthesis of epitaxial quality electronic/optical grade 2D Janus layers having the chemical formula MXY, where M is a transition metal atom (e.g., Mo, Nb, Ti, V, Cr, Mn, W, etc.) and X and Y are different chalcogen atoms (Group VIA elements, such as S, Se, or Te) is described. This synthesis is achieved without alloying. Polarization of the 2D Janus layers is a function at least in part of the chalcogens that are present (e.g., S—Se or S—Te). Synthesis methods can be used to yield 2D Janus magnets or skyrmionics (VSSe or MnSeTe) materials. Vertical hetero structures and Moire lattices can be created with different polarization direction and architecture.

When 2D Janus layers are stacked onto each other, the intrinsic polarization field acts on the neighboring layers and changes the interface properties compared to classical van der Waals (vdW) TMD heterolayers. 2D Janus homojunctions exhibit large type-II band offset (−600 meV). This phenomenon is believed to be due at least in part to band renormalization or offsetting by the intrinsic polarization acting on adjacent layers. This effect depends at least in part on the polarization direction (polarization architecture) with respect to each other. Similar ideas can be extended to 3 layer thick Janus vdW layers. Bilayer and trilayer Janus homojunctions can be fabricated with different polarization architectures (e.g., MSSe/MSSe and WSSe/WSSe homojunctions using Mo and W containing atoms).

In one example, Janus homojunctions are formed as follows. PDMS is spin coated onto 2D Janus layers and cured at 120° C. for >3 h. The PDMS/Janus layer is released from the substrate by a mild treatment in a 2 mol/L NaOH solution for ½ hours. It is then rinsed in de-ionized water to remove the KOH residue and transferred onto the other 2D Janus layers to form homojunctions. Repeating similar steps, the resulting junctions are then stamped onto the center of the diamond culet table of the DAC under an optical microscope, and the PDMS substrate is peeled off slowly, leaving, for example, the WSSe/WSSe homojunction on top of the diamond culet. The sample is aligned to a small hole (diameter ˜200 μm) drilled in a rhenium gasket and sealed by the two diamonds. Hydrostatic pressure near the sample can be determined by the standard ruby fluorescence method. The pressure medium can be the standard mixture of methanol and ethanol (4:1), or liquid argon if higher pressures are desired.

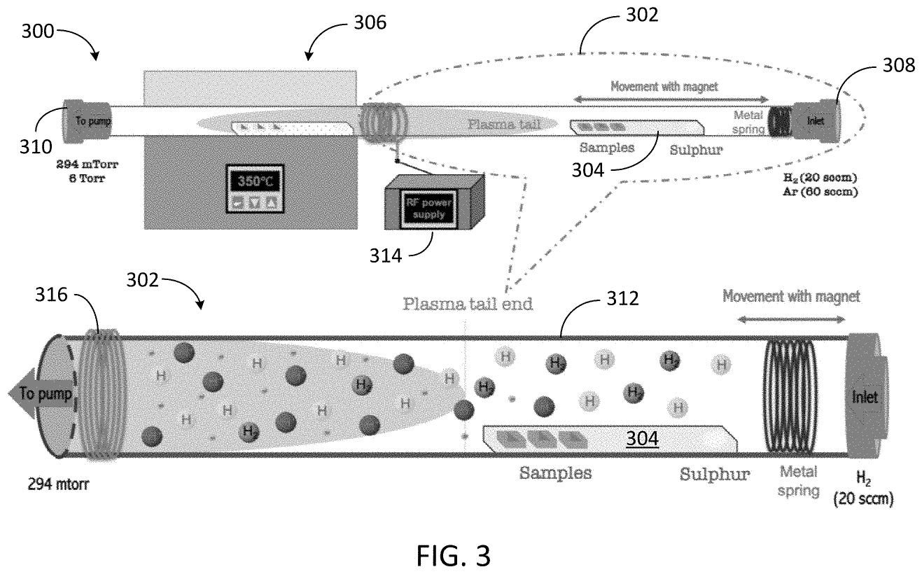

Synthesis of MoSSe is described with respect to system 300 in FIG. 3, with an enlarged portion showing plasma end tail 302. However, this method is not limited to MoSSe, and can be used for other 2D Janus layers. Synthesis of two-dimensional Janus monolayers begins with a chemical vapor deposition process, in which a substrate 304 is exposed to volatile precursors at high temperatures. These react together to form the desired monolayer (˜0.8 nm thick). Molybdenum trioxide (MoO₃) is reacted with elemental selenium (Se) in a stoichiometric ratio within a Lindberg/Blue M Furnace on the surface of a substrate in a tube furnace 306. The precursors are kept within different temperature zones within the furnace to allow for optimum growth and yield. The furnace has a gas inlet 308 on a first end and a gas outlet 310 on a second end. The reaction occurs in a process in which molybdenum trioxide is reduced to the form MoO_{(3-X)} with hydrogen gas, which then further reacts with selenium to form a MoSe₂ monolayer on the SiO_{2/}Si substrate. In some cases, many monolayer flakes are observed, with fewer contamination from bulk and MoO₃ precursors.

The selenium precursor is kept within a different temperature zone, ˜250° C., and is typically carried to the molybdenum precursor source and the substrate via a carrier gas. Argon, used as a carrier gas, can be flowed continuously through the tube 312 throughout the duration of the reaction between 40-50 SCCM. The molybdenum precursor sublimates in an excess of 800° C., and a promoter (NaCl) is added to the initial reagent to reduce its sublimation temperature. To reduce the etching effect and bulk contamination, a simultaneous flow of hydrogen gas is also maintained during the growth process. After successful growth, the flakes are verified for quality, first under an optical microscope followed by an analysis of their photoluminescence and Raman signals.

Plasma etching of the topmost selenium layer is followed by its replacement with sulfur by incorporating the principles of Reactive Ion Etching and Plasma Enhanced CVD technique simultaneously with the help of an ICP setup. This process can be carried out in a similar tube-like setup with the pressure within the tube is reduced. The etching setup includes a supported tube connected to gas lines on both ends. A vacuum pump is connected to the outlet end of the tube and a hydrogen gas supply line is connected to the inlet end. The selenium layer is etched by the means of hydrogen plasma, generated through the inductively coupled plasma setup including an RF source and a Tesla coil. The Tesla coil is wound at the center of the tube to produce plasma on both the sides of a coil. For gently stripping the top layer of selenium off of the 2D TMDC, the sample substrate is typically kept at the upstream region, in close proximity to the plasma tail end, thereby minimizing the ratio of ion concentration to neutral radicals around the locus of the sample. A small amount of sulfur to replace the etched away top layer is also kept within the upstream side in the tube. Since the dissociation of a molecule into free radical requires less energy than ionization, plasma generated from an extremely pure hydrogen gas with a constant flow rate results in the formation of hydrogen radicals beyond the scope of the visual observance of plasma inside the tube. These reactive radicals react with sulfur inside the tube and form hydrogen sulfide at the same time during the etching process of Se from 2D TMDC. In conjunction with this, there are also few hydrogen ions, and the energy around the sulfur place is such that it will form H₂S gas which is then carried over the reaction zone (substrate). These H₂S gas molecules will eventually dissociate into individual hydrogen and sulfur radicals, where these sulfur radicals combine with the freshly etched site (VSe) and form a new structure.

The distance at which the source of sulfur is positioned from the plasma tail is selected based on the RF power applied by RF power supply 314, the Tesla coil 316, and other parameters which controls the energy and density of generated plasma, such as the pressure inside tube, gas flow rate, distance of plasma tail end from the substrate and others. Sulfur supplied in the form of hydrogen sulfide helps maintain stability and avoids triggering the diffusion of selenium from the bottom layer as well as over-etching of the sample. An in situ thermal sulfurization at low temperatures (350° C.) is typically performed after etching and replacement to allow complete substitution at leftover sites during the replacement process (and to further improve the crystal quality). In-situ sulfurization has the added advantage of avoiding contamination from the ambient gases. Since the surface after etching can react with these gases, ex-situ sulfurization can result in poor quality Janus crystals. These monolayers were then verified for composition and quality using characterization techniques such as Raman, STEM, XPS, and low T-PL

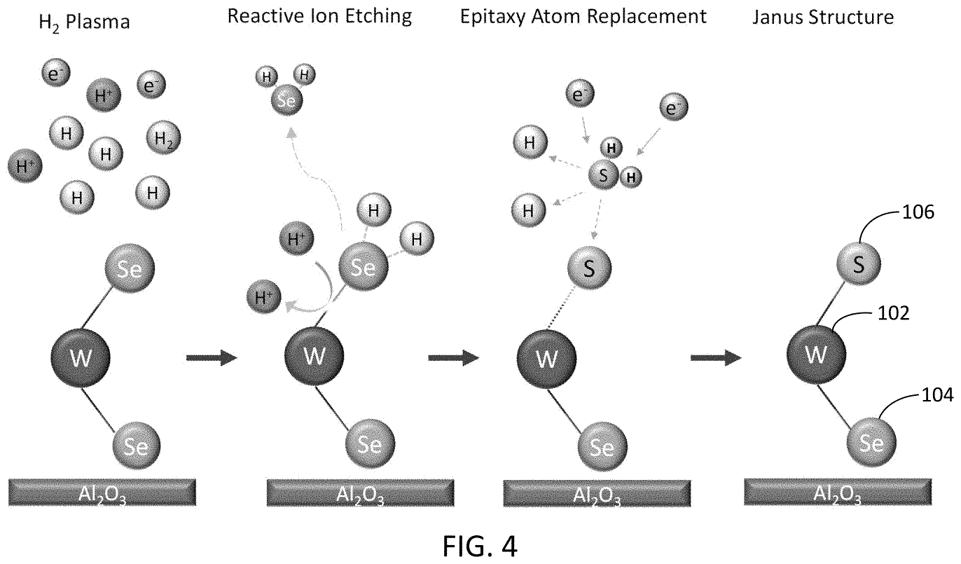

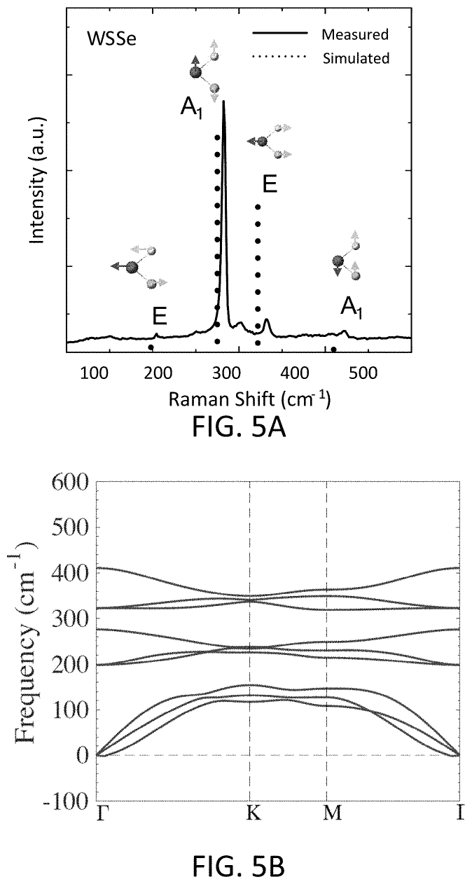

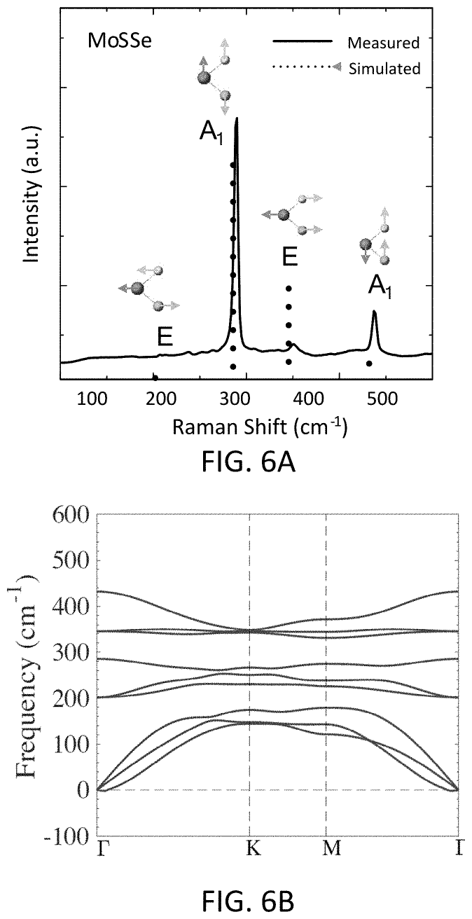

FIG. 4 depicts proposed mechanism details for the synthesis of two-dimensional (2D) Janus layers with PA-ALFM, with WSSe shown as an example. The process includes providing a hydrogen plasma, reactive ion etching, and expitaxy atom replacement, resulting in the formation of the Janus structure. FIGS. 5A and 5B show a Raman spectrum and phonon dispersion, respectively, of 2D Janus layers of WSSe formed by this process. FIGS. 6A and 6B show a Raman spectrum and phonon dispersion, respectively, of 2D Janus layers of MoSSe formed by this process.

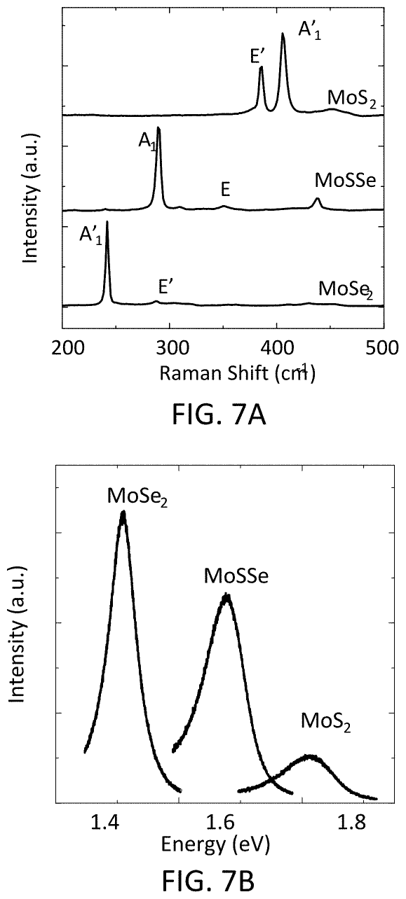

FIG. 7A shows Raman spectra of MoS₂ (top), 2D Janus layers of MoSSe (middle), and MoSe₂ (bottom). FIG. 7B shows photoluminescence (PL) spectra of MoS₂ (right), 2D Janus layers of MoSSe (middle), and MoSe₂ (left).

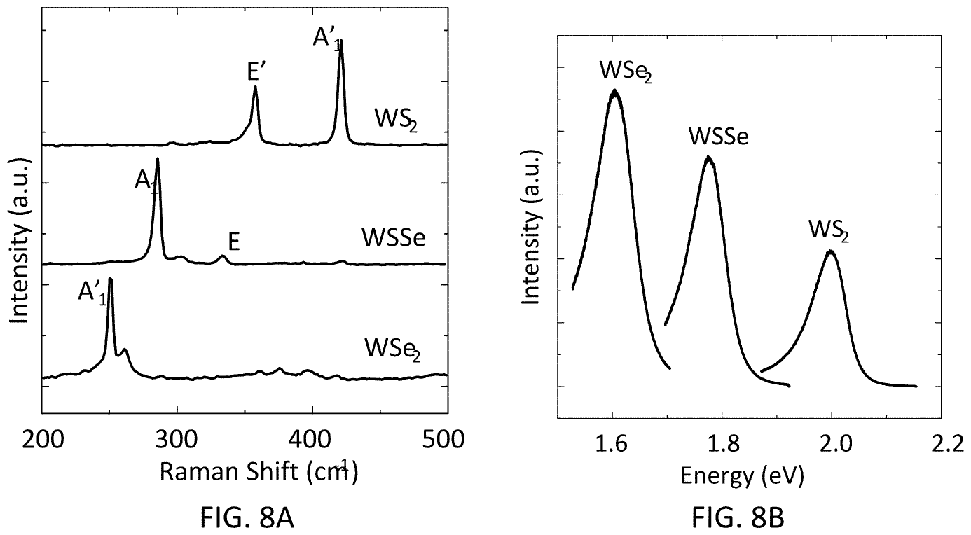

FIG. 8A shows Raman spectra of WS₂ (top), 2D Janus layers of WSSe (middle), and WSe₂ (bottom). FIG. 8B shows PL spectra of WS₂ (right), 2D Janus layers of WSSe (middle), and WSe₂ (left).

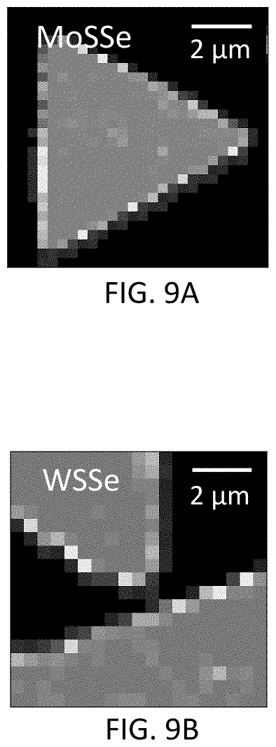

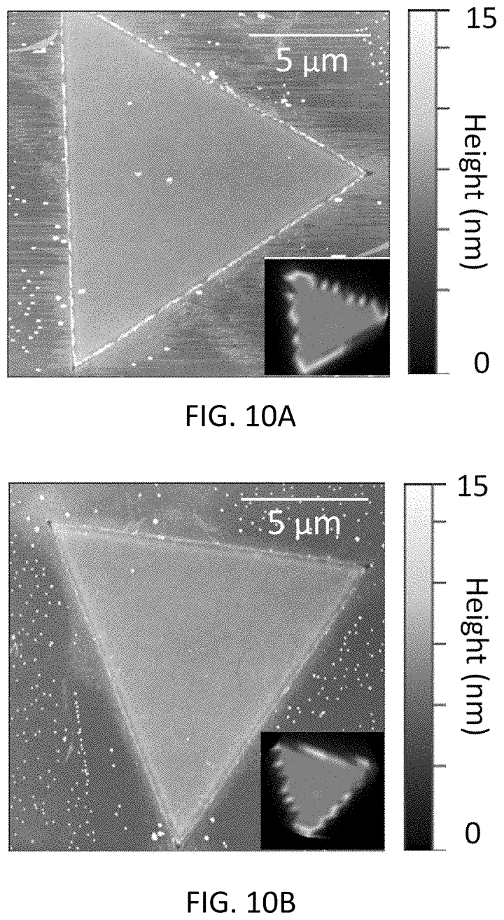

FIG. 9A shows Raman mapping of Janus MoSSe at 290 cm⁻¹. FIG. 9B shows Raman mapping of Janus WSSe at 284 cm⁻¹. FIGS. 10A and 10B show atomic force microscope (AFM) images of MoSe₂ and MoSSe, respectively. The insets show Raman mapping of peaks at 250 cm⁻¹ (WSe₂A1′ mode) and 284 cm⁻¹ (WSSeA₁ mode), respectively.

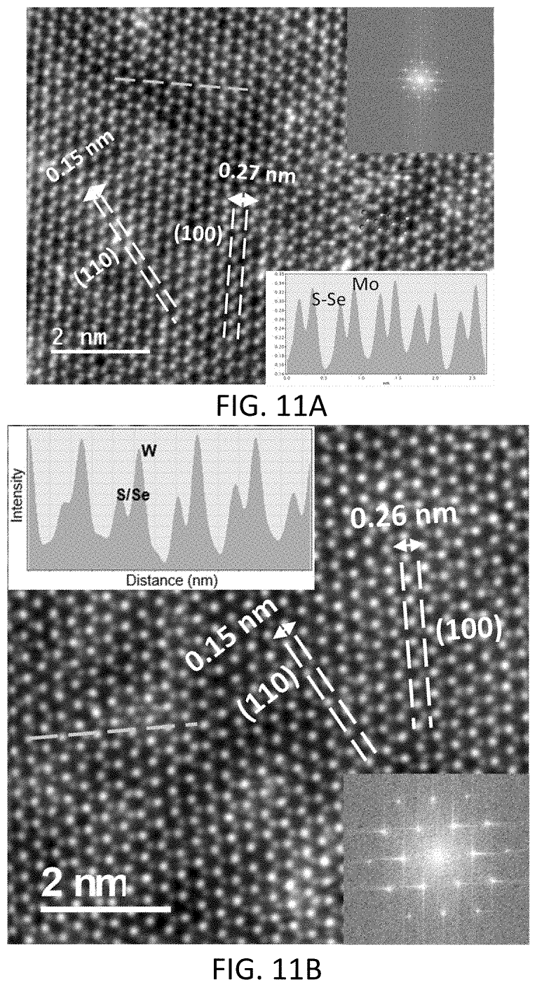

FIGS. 11A and 11B show HAADF STEM images of MoSSe and WSSe, respectively, showing hexagonal lattice structure and spacing of (100) and (110) planes. The inset shows line profile along the dashed line and FFT image.

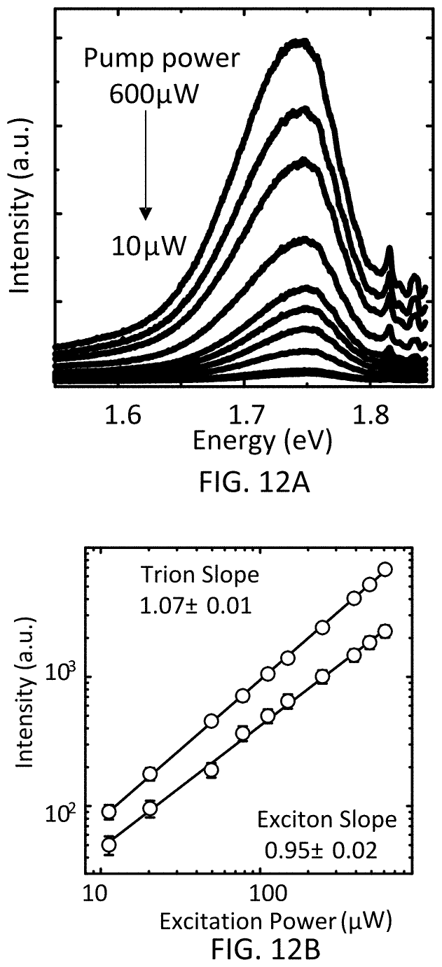

FIGS. 12A and 12B show PL spectra and integrated PL intensity, respectively, of MoSSe.

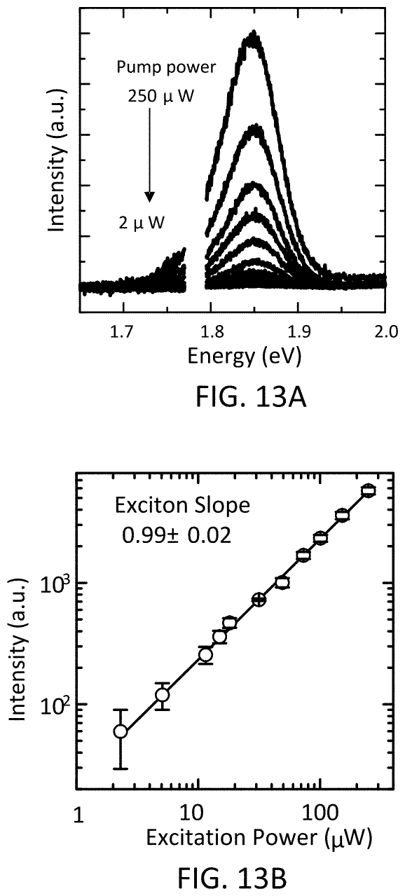

FIGS. 13A and 13B show PL spectra and integrated PL intensity, respectively, of WSSe.

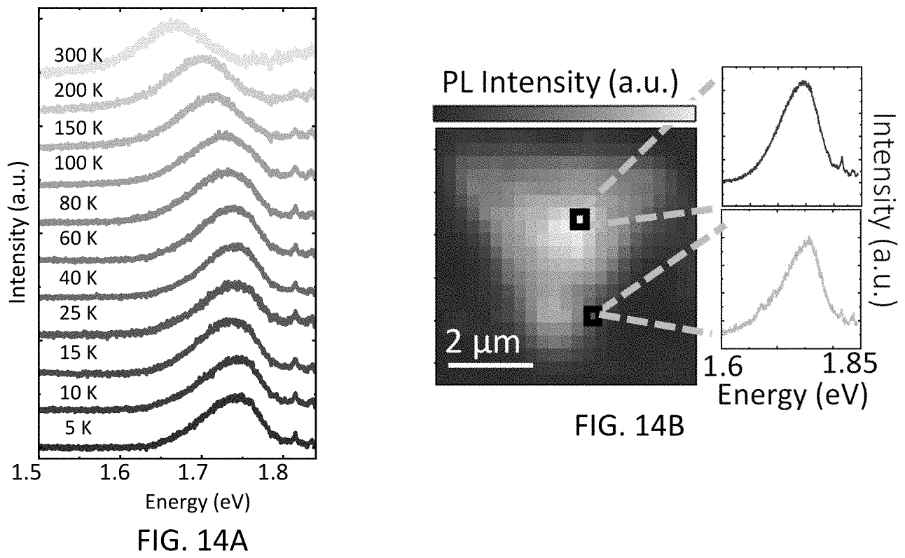

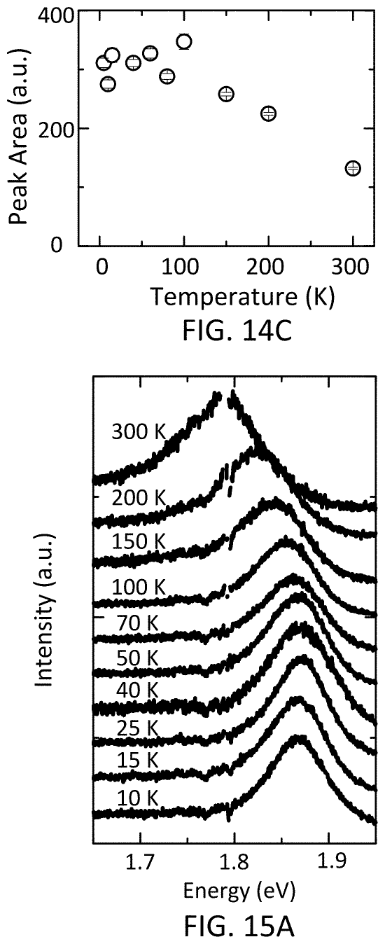

FIG. 14A shows excitonic and optical quality of synthesized Janus SeMoS monolayer evidenced by low temperature photoluminescence spectroscopy. FIG. 14B shows overall PL intensity mapping on triangular flake, and FIG. 14C shows peak area versus temperature.

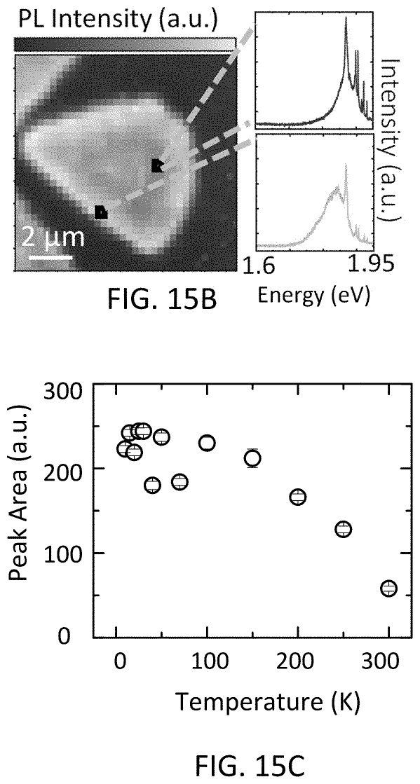

FIG. 15A shows excitonic and optical quality of synthesized Janus SeWS monolayer evidenced by low temperature photoluminescence spectroscopy. FIG. 15B shows overall PL intensity mapping on triangular flake, and FIG. 15C shows peak area versus temperature.

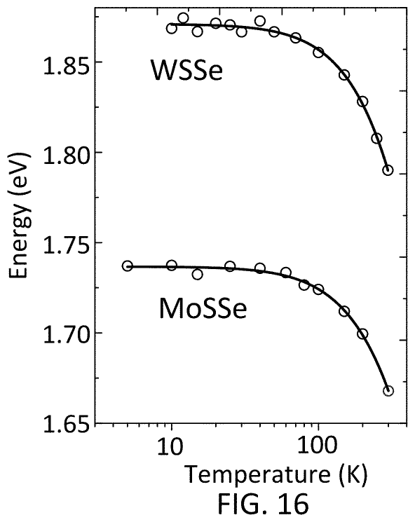

FIG. 16 shows Varshni law

$${E}_{g} ( T ) = {E}_{g} ( 0 ) - \frac{α {T}^{2}}{T + β} ,$$

and fitting of PL peak shift trend of Janus SeWS and SeMoS. A typical Varshni fitting process offers excellent fit with E₉(0)=1.87 eV, α=5.09×10⁻⁴ eV/K, β=260.02 K for WSSe and E_{g}(0)=1.74 eV, α=3.95×10⁻⁴ eV/K, β=216.71 K for MoSSe.

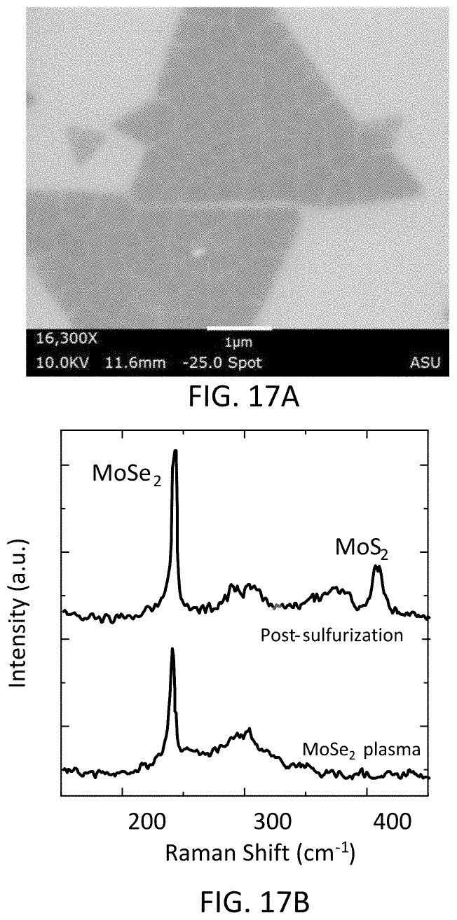

FIG. 17A is an image of Janus MoSSe showing a plasma effect with severe cracking and over etching due to intense plasma bombardment. FIG. 17B shows MoSSe Raman spectra under intense bombardment. The plasma power can be adjusted, thereby eliminating these crackings.

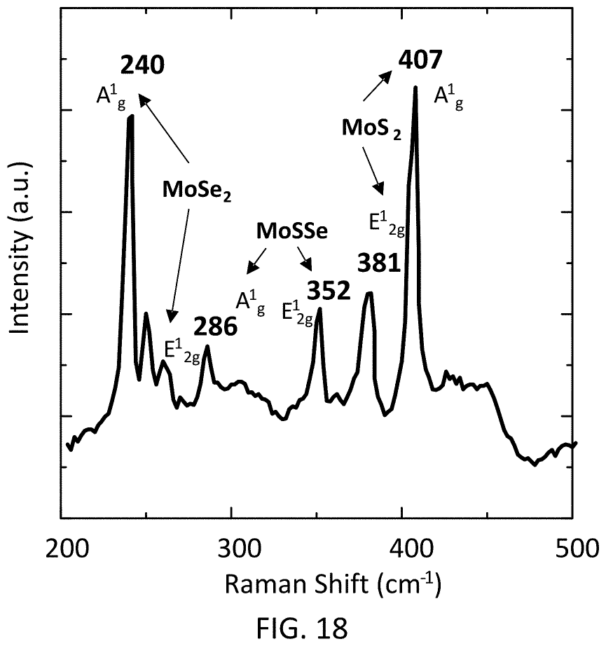

FIG. 18 shows a Raman spectrum of the randomized alloying effect while performing high temperature thermal sulfurization showing the non-repeatability of previous claims of Janus structure formation.

The evolution of Raman spectra of WSe₂ to Janus SeWS during the SEAR process with different sulfur position and a range of different SEAR processing time was explored. When the sulfur powder is placed far away from plasma tail, H₂S and S radical concentrations are significantly reduced at WSe₂ site. As such, the SEAR process is less effective and incomplete replacement can happen. As the sulfur precursor is moved closer to the sample, SEAR process becomes highly effective and Janus monolayer formation is successful. Similarly, the SEAR process time influences at least in part how much chalcogen replacement takes place. Insufficient time (12 or 15 minutes) can produce Janus layers with rather broad Raman signals. Only after sufficient time (e.g., 18 minutes) the process tends to yield highly crystalline Janus layers with a sharp Raman peak. We note that extensive processing time can be harmful since the samples undergo a longer plasma exposure.

The effect of TMDs layer distance from plasma tail on the efficiency for SEARs process was demonstrated by Raman measurements in conversion of WSe₂to Janus SeWS. When WSe₂ is placed far away, partial replacement/alloy can be observed in the Raman spectrum while when the sample is moved closer to plasma tail near optimized position, the signature A₁ Raman peak at 284 cm¹ exhibits a maximized intensity and minimized FWHM. This observation is indicative of the high crystal quality of the produced Janus SeWS. When WSe₂ is further moved towards plasma tail, the increased density of energetic ions etches away both top and bottom Se layers, rendering defected material that has no distinctive Raman peaks.

Tilted angle STEM images showed that the structure formed in the SEAR process is indeed Janus instead of a random alloy.

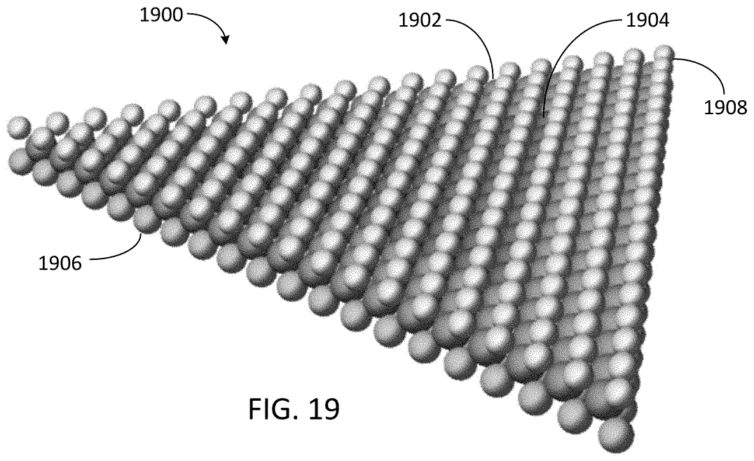

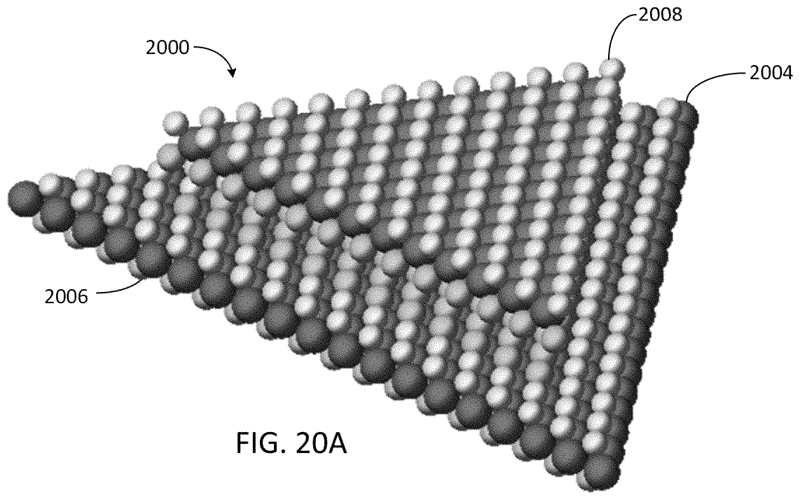

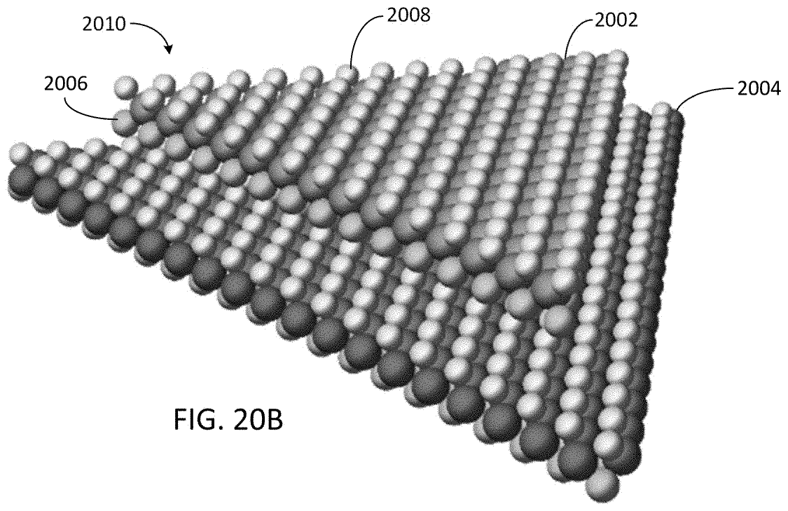

The controlled and mild nature of SEAR process allows for not only Janus monolayer conversion, but also formation of related heterostructures. This include lateral heterostructures (e.g., SeMoS—SeWS lateral heterostructures), vertical heterostructures (e.g., WSe₂/SeWS vertical heterostructures and SeMoS/SeWS vertical heterostructures). FIG. 19 depicts a lateral Janus heterostructure 1900. Although other lateral Janus heterostructures are possible, lateral Janus heterostructure 1900 is a WSSe/MoSSe structure with Mo atoms 1902, W atoms 1904, Se atoms 1906, and S atoms 1908. FIGS. 20A and 20B depict vertical Janus heterostructures. In FIG. 20A, vertical Janus heterostructure 2000 is a SeWS/WSe₂ structure with W atoms 2004, Se atoms 2006, and S atoms 2008. In FIG. 20B, vertical Janus heterostructure 2010 is a WSSe/MoSSe structure with Mo atoms 2002, W atoms 2004, Se atoms 2006, and S atoms 2008.

Although this disclosure contains many specific embodiment details, these should not be construed as limitations on the scope of the subject matter or on the scope of what may be claimed, but rather as descriptions of features that may be specific to particular embodiments. Certain features that are described in this disclosure in the context of separate embodiments can also be implemented, in combination, in a single embodiment. Conversely, various features that are described in the context of a single embodiment can also be implemented in multiple embodiments, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

What is claimed is:

1. A method of forming a two-dimensional Janus layer, the method comprising:
forming a layer comprising MX₂, wherein M is a transition metal and X is a first chalcogen;
plasma etching the layer comprising MX₂ to remove X from the top layer, thereby yielding an etched layer; and
contacting the etched layer with a second chalcogen Y, wherein the second chalcogen is different than the first chalcogen, thereby yielding a two-dimensional Janus layer comprising MXY.

2. The method of claim 1, wherein forming the layer comprising MX₂ comprises reacting a transition metal-containing compound with a chalcogen in a tube furnace to yield a transition metal-containing chalcogenide compound.

3. The method of claim 2, wherein reacting the transition metal-containing chalcogenide compound with the hydrogen radicals removes a layer of a chalcogen surface to yield a reduced transition-metal containing compound.

4. The method of claim 1, further comprising reacting the reduced transition metal-containing compound with the first chalcogen to yield the layer comprising MX₂.

5. The method of claim 1, wherein removing X and adding Y occurs simultaneously.

6. The method of claim 1, wherein the transition metal is selected from the group consisting of Mo, Nb, Ti, V, Cr, Mn, and W.

7. The method of claim 1, wherein the first chalcogen and the second chalcogen are selected from the group consisting of O, S, Se, and Te.

8. The method of claim 1, wherein plasma etching the layer comprising MX₂ occurs at a pressure less than atmospheric pressure.

9. The method of claim 1, wherein plasma etching comprises etching with a hydrogen plasma comprising hydrogen radicals.

10. The method of claim 9, further comprising reacting hydrogen free radicals from the hydrogen plasma with the second chalcogen to yield H₂Y.

11. The method of claim 10, wherein H₂Y dissociates to yield Y radicals.

12. The method of claim 11, wherein contacting the etched layer with the second chalcogen comprises reacting the Y radicals with the etched layer.

13. The method of claim 1, wherein the layer comprising MX₂ is positioned proximate a tail of the plasma.

14. The method of claim 1, further comprising thermal sulfurization of the layer comprising MXY.

15. The method of claim 1, wherein the two-dimensional Janus layer is a monolayer.

16. The method of claim 1, wherein the two-dimensional Janus layer is formed without alloying.

17. A two-dimensional Janus layer formed by the method of claim 1.

18. The two-dimensional Janus layer of claim 17, wherein the two-dimensional Janus layer lacks inversion symmetry and mirror symmetry.

19. The two-dimensional Janus layer of claim 17, wherein the two-dimensional Janus layer has a thickness of about 1 nm.

20. The method of claim 1, wherein the method occurs at room temperature and yields lateral and vertical heterojunctions of Janus layers.
